(19) United States
(12) Patent Application Publication
(10) Pub. No.: US 2016/0079252 A1
(43) Pub. Date: Mar. 17, 2016

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventor: Hiroki YAMASHITA, Yokkaichi (JP)

(73) Assignee: Kabushiki Kaisha Toshiba, Minato-ku (JP)

(21) Appl. No.: 14/796,611

(22) Filed: Jul. 10, 2015

Related U.S. Application Data
(60) Provisional application No. 62/049,208, filed on Sep. 11, 2014.

(51) Int. Cl. H01L 27/115; H01L 29/66

(52) U.S. Cl. CPC H01L 27/11551; H01L 27/11524; H01L 29/66825; H01L 27/11543

(57) ABSTRACT

According to one embodiment, a semiconductor memory device includes a semiconductor pillar extending in a first direction, a first insulating film, a second insulating film, a third insulating film, a first portion of a first electrode provided to be in contact with an outer surface of the first insulating film, a second portion of the first electrode provided to be in contact with an outer surface of the first insulating film, a third portion of the first electrode provided to be in contact with the first insulating film, a forth insulating film provided on an outer surface of the first electrode, and a second electrode provided on an outer surface of the forth insulating film. An outer diameter of the first portion is larger than an outer diameter of the third portion.

### CROSS-REFERENCE TO RELATED APPLICATIONS

This application is based upon and claims the benefit of priority from U.S. Provisional Patent Application 62/049,208, filed on Sep. 11, 2014; the entire contents of which are incorporated herein by reference.

### FIELD

Embodiments described herein relate generally to a semiconductor memory device and a method for manufacturing the same.

### BACKGROUND

In the related art, in accordance with progresses for high-integration of semiconductor memory devices, a stacked semiconductor memory device has been proposed. Since delicate processing is required for lithography and etching in manufacturing the stacked semiconductor memory device, a vertical channel type requiring lithography and etching only once at critical dimension has become a main stream.

### BRIEF DESCRIPTION OF THE DRAWINGS

FIG. 1 is a cross-sectional view illustrating the semiconductor memory device according to a first embodiment;

FIG. 2 is a perspective view illustrating a portion shown in FIG. 1;

FIGS. 3 to 5 are cross-sectional views illustrating the method for manufacturing a semiconductor memory device according to the first embodiment;

FIGS. 6 to 14 are cross-sectional views illustrating a method for manufacturing a portion B shown in FIG. 5, in a semiconductor memory device according to the first embodiment;

FIG. 15 is a cross-sectional view of the semiconductor memory device shown in FIG. 14 seen in the Z-direction;

FIGS. 16 to 19 are cross-sectional view illustrating the method for manufacturing the portion B shown in FIG. 5, in a semiconductor memory device according to the first embodiment;

FIG. 20 is a cross-sectional view illustrating the method for manufacturing a semiconductor memory device according to the first embodiment;

FIG. 21 is a cross-sectional view illustrating the semiconductor memory device according to a comparison example of the first embodiment;

FIGS. 22 to 24 are cross-sectional views illustrating a method for manufacturing a semiconductor memory device according to a variation of the first embodiment;

FIGS. 25 to 30 are cross-sectional views illustrating the method for manufacturing a semiconductor memory device according to a second embodiment; and

FIGS. 31 and 32 are cross-sectional views illustrating the method for manufacturing a semiconductor memory device according to a variation of the second embodiment.

### DETAILED DESCRIPTION

According to one embodiment, a semiconductor memory device includes a semiconductor pillar extending in a first direction, a first insulating film provided on a side surface of the semiconductor pillar, a second insulating film provided on a side surface of the first insulating film, a third insulating film provided apart from the second insulating film on a side surface of a second direction opposite to the first direction of the first insulating film, a first portion of a first electrode provided in a space between the second insulating film and the third insulating film so as to be in contact with an outer surface of the first insulating film and a surface of the second direction side of the second insulating film, a second portion of the first electrode provided in a space between the second insulating film and the third insulating film so as to be in contact with an outer surface of the first insulating film and a surface of the first direction side of the third insulating film, a third portion of the first electrode provided in a space between the first portion of the first electrode and the second portion of the first electrode so as to be in contact with the first insulating film, the first portion of the first electrode and the second portion of the first electrode, a forth insulating film provided on an outer surface of the first electrode, a surface of the second direction side of the second insulating film and a surface of the first direction side of the third insulating film between the second insulating film and the third insulating film, and a second electrode provided on an outer surface of the forth insulating film between the second insulating film and the third insulating film. An outer diameter of the first portion of the first electrode is larger than an outer diameter of the third portion of the first electrode, an outer diameter of the second portion of the first electrode is larger than an outer diameter of the third portion of the first electrode.

According to one embodiment, a method for manufacturing a semiconductor memory device includes forming of a first material layer performed by causing a first material to be accumulated, forming of a second material layer performed by causing a second material to be accumulated on the first material layer, forming of a third material layer performed by causing a third material to be accumulated on the second material layer. The method for manufacturing the semiconductor memory device also includes forming of a memory hole performed by penetrating a stacked body composed of the first material layer, the second material layer, and the third material layer in a stacking direction. The method for manufacturing the semiconductor memory device also includes removing of a portion of the second material layer on the memory hole side through the memory hole, causing a first conductive material to be accumulated in the memory hole. The method for manufacturing the semiconductor memory device also includes forming of a first portion of a first electrode made of the first conductive material in a space after the second material layer is removed, by performing etch-back on the first conductive material. The method for manufacturing the semiconductor memory device also includes removing a portion of each of the first material layer and the third material layer on the memory hole side through the memory hole, causing of a second conductive material to be accumulated in the memory hole. The method for manufacturing the semiconductor memory device also includes forming of a second portion of the first electrode made of the second conductive material in a first direction side space after the first material layer and the third material layer are removed, forming of a third portion of the first electrode made of the second conductive material in a second direction side being opposite to the first direction side space after the first material layer and the third material layer are removed, by performing etch-back on the second material layer. The method for manufacturing the semiconductor memory device also includes forming of a first insulating film on side surfaces of the first electrode, forming of a slit penetrating the stacked body in the stacking direction on sides of the memory hole. The method for manufacturing the semiconductor memory device also includes removing of the first material layer, the second material layer, and the third material layer through the slit. The method for manufacturing the semiconductor memory device also includes forming of a second insulating film on side surfaces of the first electrode through the slit and forming of a second electrode on a front surface of the second insulating film through the slit.

Hereinafter, with reference to the drawings, embodiments of the invention will be described.

### First Embodiment

Firstly, a configuration of a semiconductor memory device according to the embodiment will be described.

The semiconductor memory device according to the embodiment is a FG (Floating Gate) type stacked NAND flash memory.

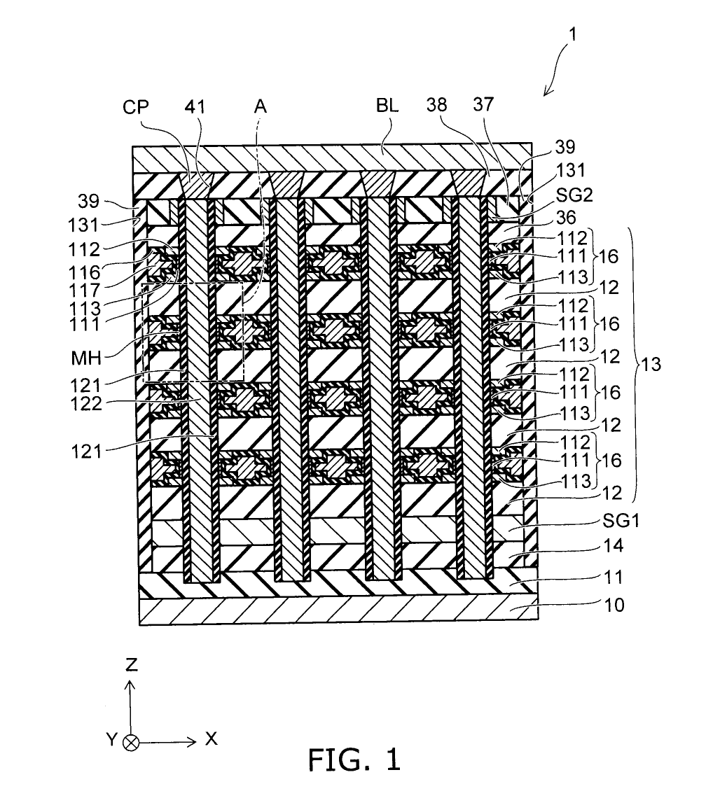

FIG. 1 is a cross-sectional view illustrating the semiconductor memory device according to the embodiment.

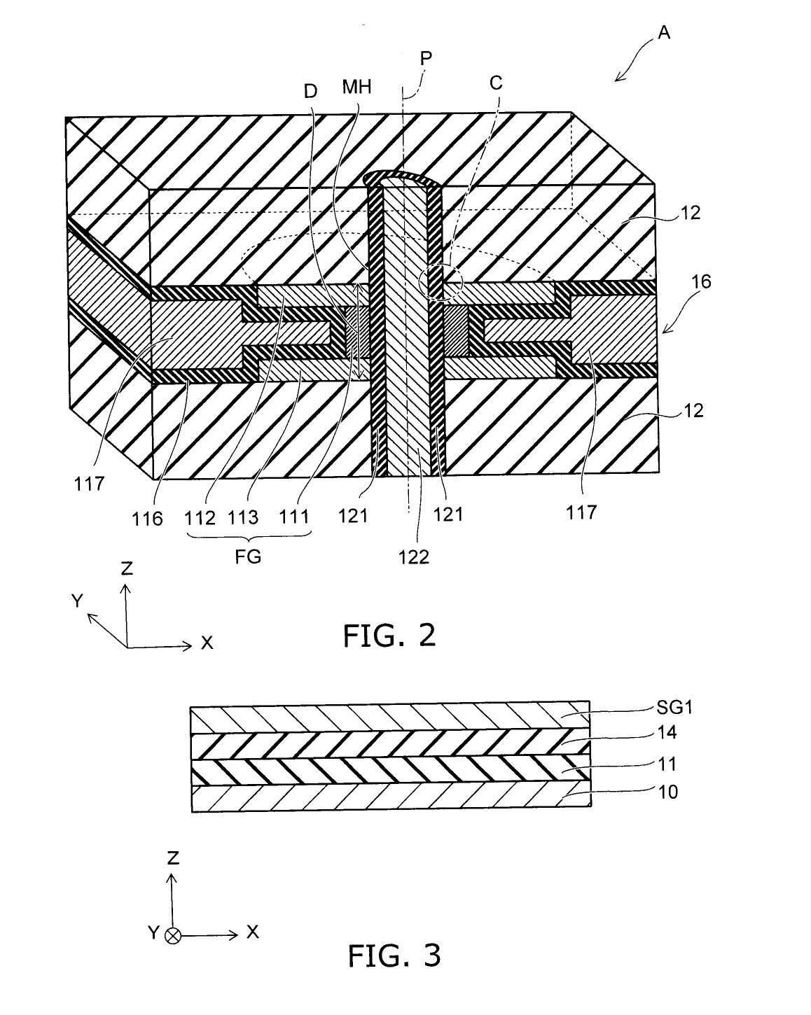

FIG. 2 is a perspective view illustrating a portion shown in FIG. 1.

As shown in FIG. 1, a semiconductor memory device 1 according to the embodiment is provided with a substrate 10, and a well layer 11 is provided on the substrate 10.

Hereinafter, for convenience of description, an XYZ rectangular coordinate system is employed in the specification. In other words, in FIG. 1, two directions parallel to a contact surface of the substrate 10 and the well layer 11 and orthogonal to each other are an “X-direction” and a “Y-direction”. An upward direction perpendicular to the contact surface of the substrate 10 and the well layer 11 is a “Z-direction” or a “first direction”. An opposite direction of the “first direction” is a “second direction”.

An insulating film 14, a selector gate electrode SG1, a stacked body 13, an interlayer insulating film 36, selector gate electrodes SG2, interlayer insulating films 37, an interlayer insulating film 38 and bit lines BL are provided on the well layer 11 along the Z-direction from below. The stacked body 13 is formed of interlayer insulating films 12 and linear structure bodies 16 which are alternately stacked. The selector gate electrodes SG2 are separated in the X-direction and extend in the Y-direction. The interlayer insulating films 37 are embedded in gaps between the selector gate electrodes SG2.

Memory holes MH are formed on the well layer 11 so as to penetrate a stacked body within a range from the selector gate electrodes SG2 and the well layer 11 in the Z-direction. Tunnel insulating films 121 are provided on side surfaces of the memory hole MH. A silicon pillar 122 is provided on a central axis side from the tunnel insulating films 121.

Contact plugs CP embedded in the interlayer insulating film 38 are provided on the silicon pillars 122. The bit lines BL separated in the Y-direction and extending in the X-direction are provided on the contact plugs CP.

As shown in FIG. 2, the linear structure body 16 is formed of a floating gate electrode 111, a floating gate electrode 112, a floating gate electrode 113, an inter-electrode insulating film 116 and a control gate electrode 117.

The floating gate electrode 113 is provided on a side surface of the tunnel insulating film 121, and of which a cross section has a quadrangular ring shape. The floating gate electrode 111 is provided on the side surface of the tunnel insulating film 121, and of which a cross section has a quadrangular ring shape. The floating gate electrode 112 is provided on the side surface of the tunnel insulating film 121, and of which a cross section has a quadrangular ring shape. The floating gate electrode 111, the floating gate electrode 112 and the floating gate electrode 113 collectively form a floating gate electrode FG.

The floating gate electrode 112 and the floating gate electrode 113 having the same shape are mutually distal, and the floating gate electrode 111 is provided therebetween. Since an outer diameter of the floating gate electrode 111 is smaller than outer diameters of the floating gate electrode 112 and the floating gate electrode 113, a ring-shaped concave portion is formed on an outer side surface of the floating gate electrode FG, and the control gate electrode 117 enters the concave portion.

The control gate electrode 117 has a flat shape parallel to an X-Y plane, and a hole is open in the control gate electrode 117 so as to accommodate the floating gate electrode FG. A convex portion is formed inside the hole toward a central axis P of the silicon pillar 122.

The inter-electrode insulating film 116 is provided between the structure body composed of the floating gate electrode 112, the floating gate electrode 113, the floating gate electrode 111 and the insulating film 12, and the control gate electrode 117.

A length in the Z-direction of a contact portion between the tunnel insulating film 121 and the floating gate electrode FG is referred to as a channel width D. In the semiconductor memory device 1 according to the embodiment, since the tunnel insulating film 121 and the inter-electrode insulating film 116 are not in contact with each other, the channel width D can be widened.

The floating gate electrode FG is formed of silicon (Si) in which phosphorus (p) or boron (B) is doped, for example. The interlayer insulating film 12 is formed of silicon oxide (SiO₂), for example. The inter-electrode insulating film 116 is formed of a single layer film of silicon oxide; a stacked film made of silicon oxide and silicon nitride (SiN); a single layer film made of a high dielectric constant insulating material; or a stacked film made of a high dielectric constant insulating material, silicon oxide and silicon nitride, for example.

The high dielectric constant insulating material is oxide or oxynitride of one or more types of metal selected from a group composed of zirconium (Zr), hafnium (Hf), tantalum (Ta), lanthanum (La) and aluminum (Al), for example.

Electrical potentials of the silicon pillar 122 and the control gate electrode 117 are individually controllable by peripheral circuits (not shown). Accordingly, in the semiconductor memory device 1, electrical charges can be accumulated in an arbitrary floating gate electrode FG by controlling the electrical potentials of the silicon pillar 122 and the control gate electrode 117 and moving electrons between the silicon pillar 122 and the floating gate electrode FG. As a result, data can be stored in the floating gate electrode FG. In other words, in the semiconductor memory device 1, each floating gate electrode FG is configured to have a memory cell.

Subsequently, a method for manufacturing a semiconductor memory device according to the embodiment will be described.

FIGS. 3 to 5 are cross-sectional views illustrating the method for manufacturing a semiconductor memory device according to the embodiment.

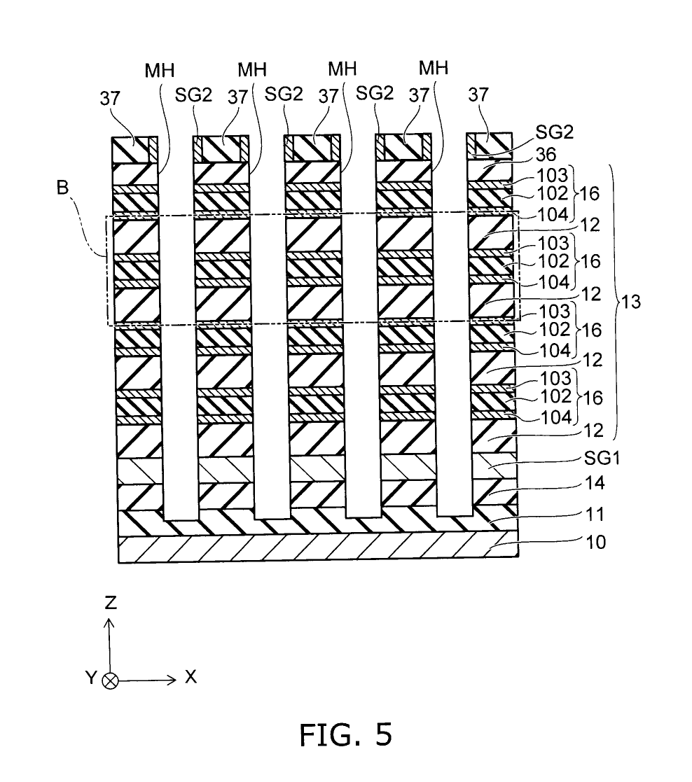

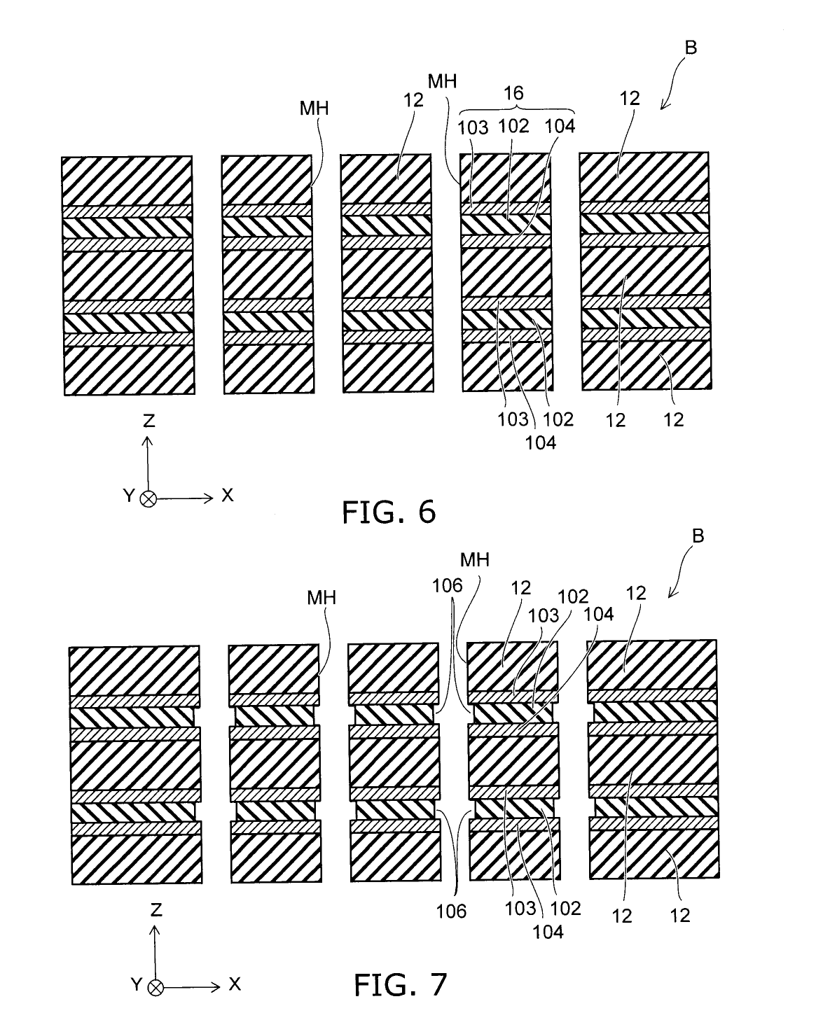

FIGS. 6 to 14 are cross-sectional views illustrating a method for manufacturing a portion B shown in FIG. 5, in a semiconductor memory device according to the embodiment.

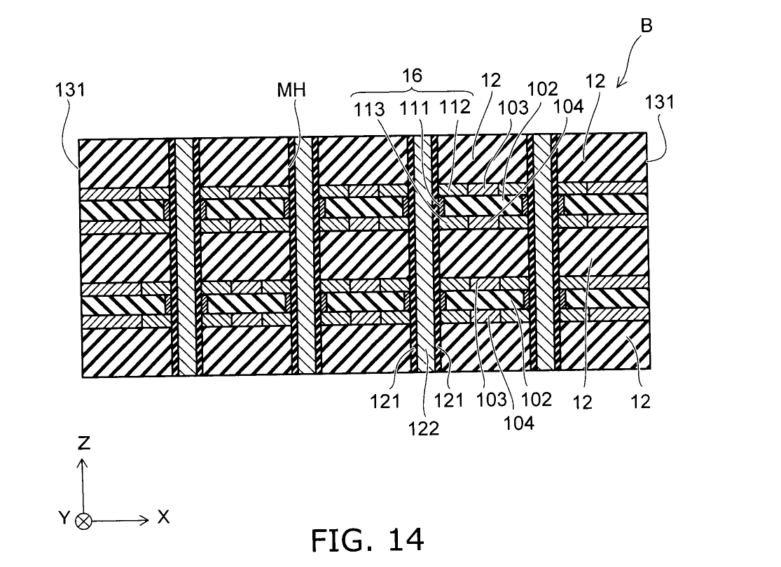

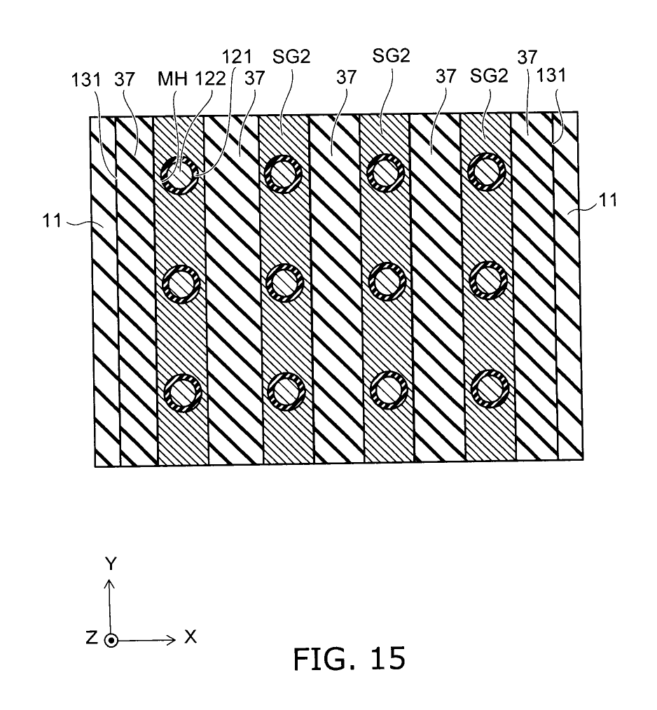

FIG. 15 is a cross-sectional view of the semiconductor memory device shown in FIG. 14 seen in the Z-direction.

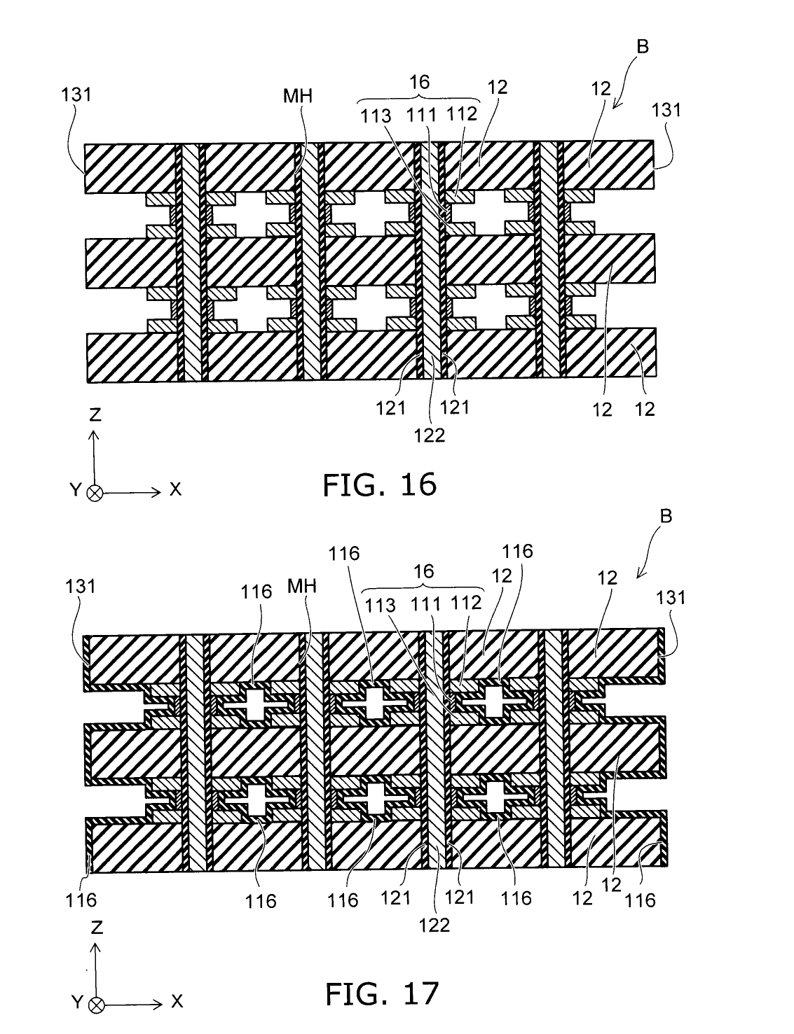

FIGS. 16 to 19 are cross-sectional view illustrating the method for manufacturing the portion B shown in FIG. 5, in a semiconductor memory device according to the embodiment.

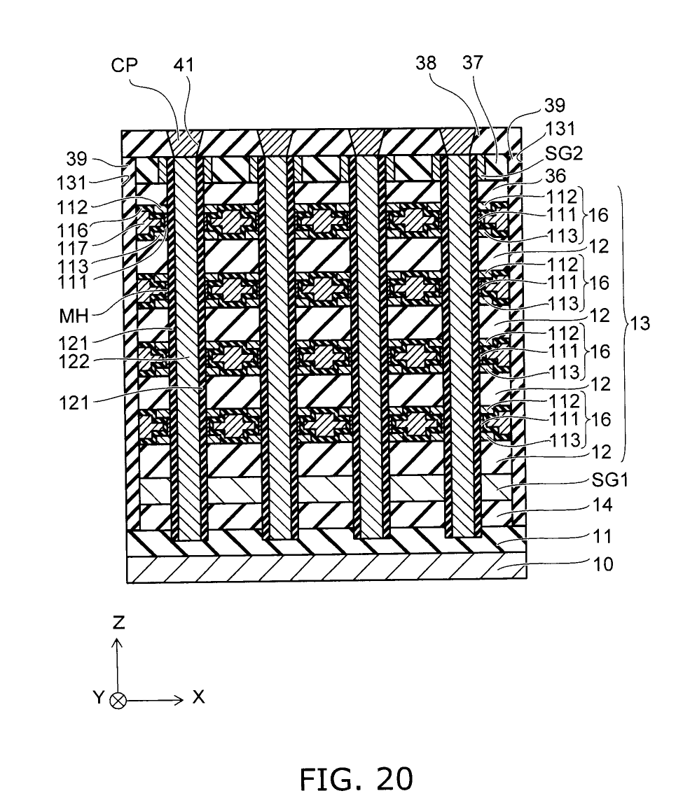

FIG. 20 is a cross-sectional view illustrating the method for manufacturing a semiconductor memory device according to the embodiment.

As shown in FIG. 3, for example, the well layer 11 made of silicon oxide is formed on the substrate 10 by a high density plasma chemical vapor deposition (HDP-CVD) method, and the insulating film 14 is formed thereon. Thereafter, the selector gate electrode SG1 is formed on the insulating film 14.

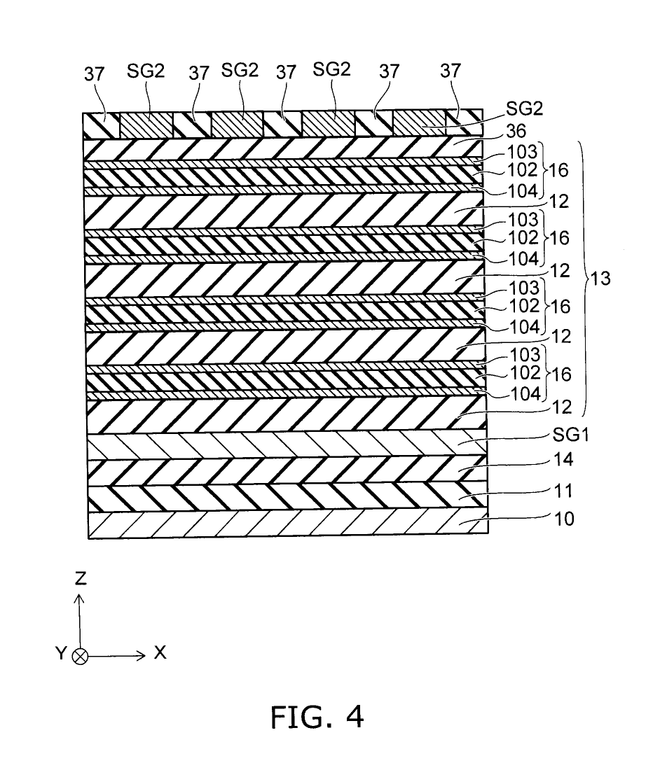

Subsequently, as shown in FIG. 4, the interlayer insulating films 12 and the linear structure bodies 16 are alternately stacked on the selector gate electrode SG1, thereby forming the stacked body 13. The linear structure body 16 is formed by stacking a conductive film 104 made of silicon (Si), for example; an insulating film 102 made of silicon oxide (SiN), for example; and a conductive film 103 made of silicon, for example, on the interlayer insulating film 12 in order. Thereafter, the interlayer insulating film 36 is formed on the stacked body 13. Thereafter, the selector gate electrodes SG2 extending in the Y-direction and separated in the X-direction are formed on the interlayer insulating film 36. Thereafter, the interlayer insulating films 37 are embedded in gaps between the selector gate electrodes SG2.

Subsequently, as shown in FIGS. 5 and 6, for example, reactive ion etching (RIE) is performed to form the memory hole MH penetrating the stacked body within the range from the selector gate electrodes SG2 to the well layer 11 in the Z-direction.

Subsequently, as shown in FIG. 7, for example, etch-back is performed on the insulating film 102 through the memory hole MH by chemical dry etching (CDE) in which hot phosphoric acid is used as an etching solution, thereby removing a portion of the insulating film 102 on the memory hole MH side. As a result, a concave portion 106 is formed on a side surface of the memory hole MH.

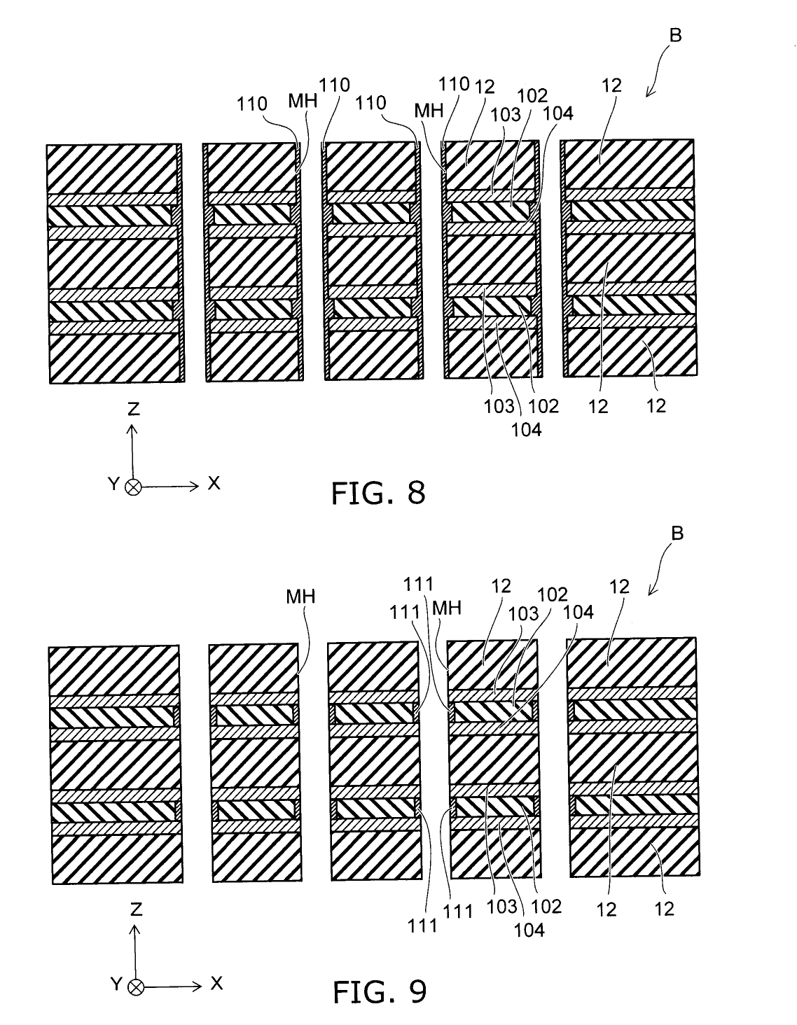

Subsequently, as shown in FIG. 8, silicon (Si) in which phosphorus (P) or boron (B) is doped is accumulated on the side surface of the memory hole MH and in the concave portion 106 by a low pressure chemical vapor deposition (LP-CVD) method, for example, thereby forming a conductive member 110.

Subsequently, as shown in FIG. 9, RIE is performed to remove the conductive member 110 in the memory hole MH but the conductive member 110 remains in the concave portion 106, thereby forming the floating gate electrode 111 in a portion inside the insulating film 102 on a memory hole side. The floating gate electrode 111 is annularly formed so as to surround the memory hole MH.

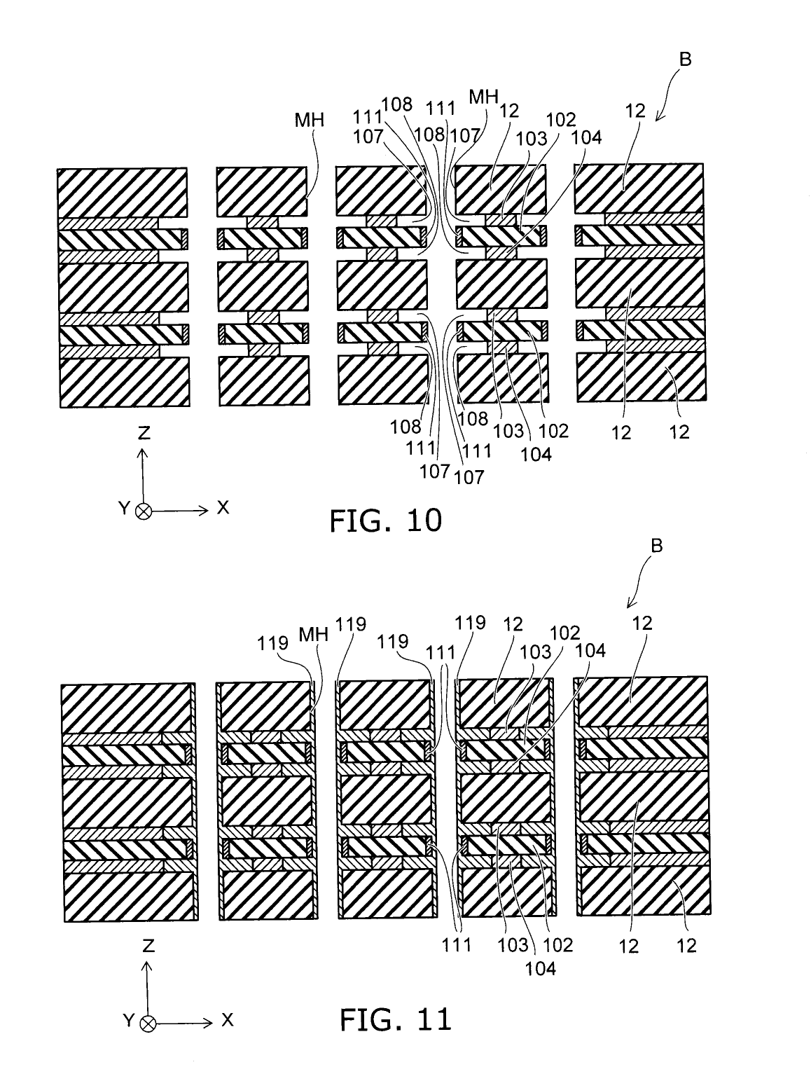

Subsequently, as shown in FIG. 10, for example, etch-back is performed on the conductive film 103 and the conductive film 104 through the memory hole MH by CDE in which a hot choline aqueous solution is used as an etching solution, thereby removing a portion of each of the conductive film 103 and the conductive film 104 on the memory hole MH side. As a result, a concave portion 107 is formed in a portion of the conductive film 103 on the memory hole MH side, and a concave portion 108 is formed in a portion of the conductive film 104 on the memory hole MH side. In this case, since the preformed floating gate electrode 111 is resistant to a hot choline aqueous solution, the floating gate electrode 111 is not removed by a hot choline aqueous solution.

Subsequently, as shown in FIG. 11, silicon in which phosphorus or boron is doped is accumulated on a side surface of the memory hole MH, and in the concave portion 107 and the concave portion 108 by the LP-CVD method, for example, thereby forming a conductive member 119.

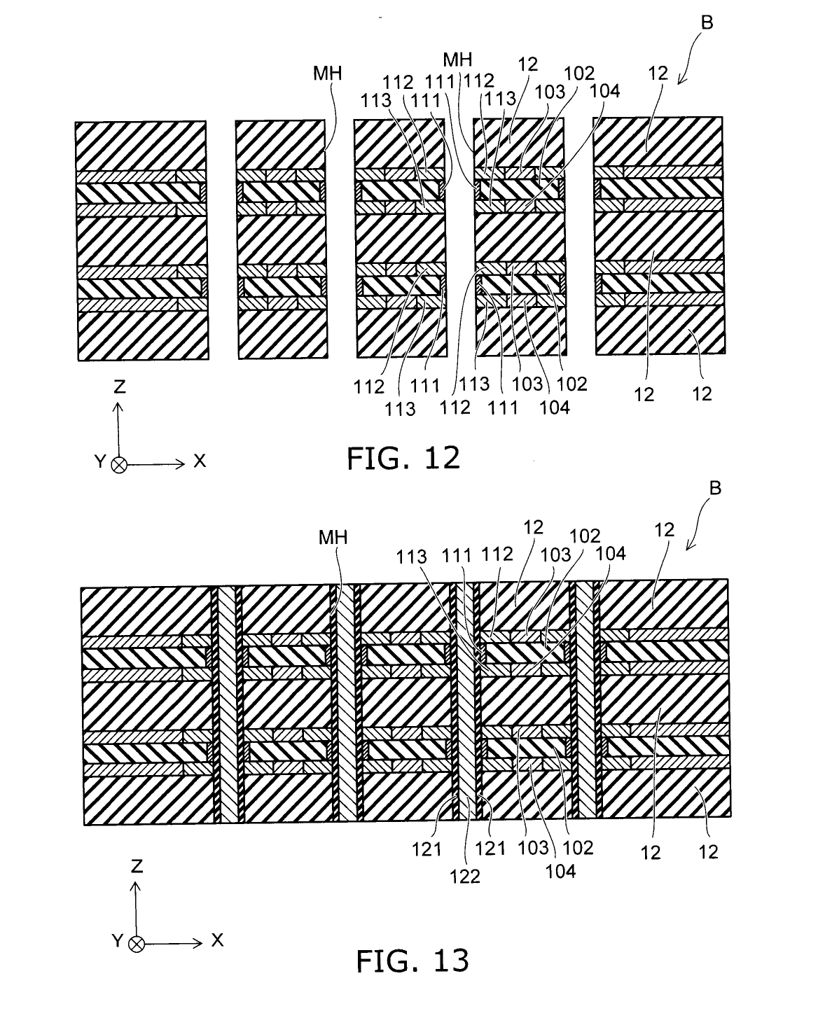

Subsequently, as shown in FIG. 12, RIE is performed to remove the conductive member 119 in the memory hole MH but the conductive member 119 remains in the concave portion 107 and the concave portion 108, thereby forming the floating gate electrode 112 in a portion inside the conductive film 103 on a memory hole side. In addition, the floating gate electrode 113 is formed in a portion inside the conductive film 104 on a memory hole side. The floating gate electrode 112 and the floating gate electrode 113 are annularly formed so as to surround the memory hole MH.

Subsequently, as shown in FIG. 13, silicon oxide (SiO₂), for example, is accumulated on a side surface of the memory hole MH by the LP-CVD method, thereby forming the tunnel insulating film 121. Otherwise, an oxide-nitride-oxide film (ONO film) is formed by the LP-CVD method so as to be used as the tunnel insulating film 121. Thereafter, silicon, for example, is accumulated in the memory hole MH by the LP-CVD method, thereby forming the silicon pillar 122.

Subsequently, as shown in FIGS. 14 and 15, for example, RIE is performed to form rear surface slits 131 penetrating a stacked body within a range from the selector gate electrodes SG2 to the insulating film 14 in the Z-direction. The rear surface slits 131 are respectively formed in four silicon pillars 122 in the X-direction, for example. The rear surface slits 131 extend in the Y-direction.

Subsequently, as shown in FIG. 16, for example, the conductive film 103 and the conductive film 104 are removed through the rear surface slits 131 by using a hot choline aqueous solution as an etching solution. Thereafter, the insulating film 102 is similarly removed through the rear surface slits 131 by using hot phosphoric acid as an etching solution. In this case, since the preformed floating gate electrode FG is resistant to a hot choline aqueous solution and hot phosphoric acid, the preformed floating gate electrode FG is not removed by a hot choline aqueous solution and hot phosphoric acid.

Subsequently, as shown in FIG. 17, silicon oxide (SiO₂), for example, is accumulated in the linear structure body 16 through the rear surface slits 131 and on side surfaces of the rear surface slits 131 by the LP-CVD method, thereby forming the inter-electrode insulating film 116. Otherwise, the ONO film is formed by the LP-CVD method so as to be used as the inter-electrode insulating film 116. Furthermore, a high dielectric constant insulating film is formed with a high dielectric constant insulating material by the LP-CVD method so as to be used as the inter-electrode insulating film 116.

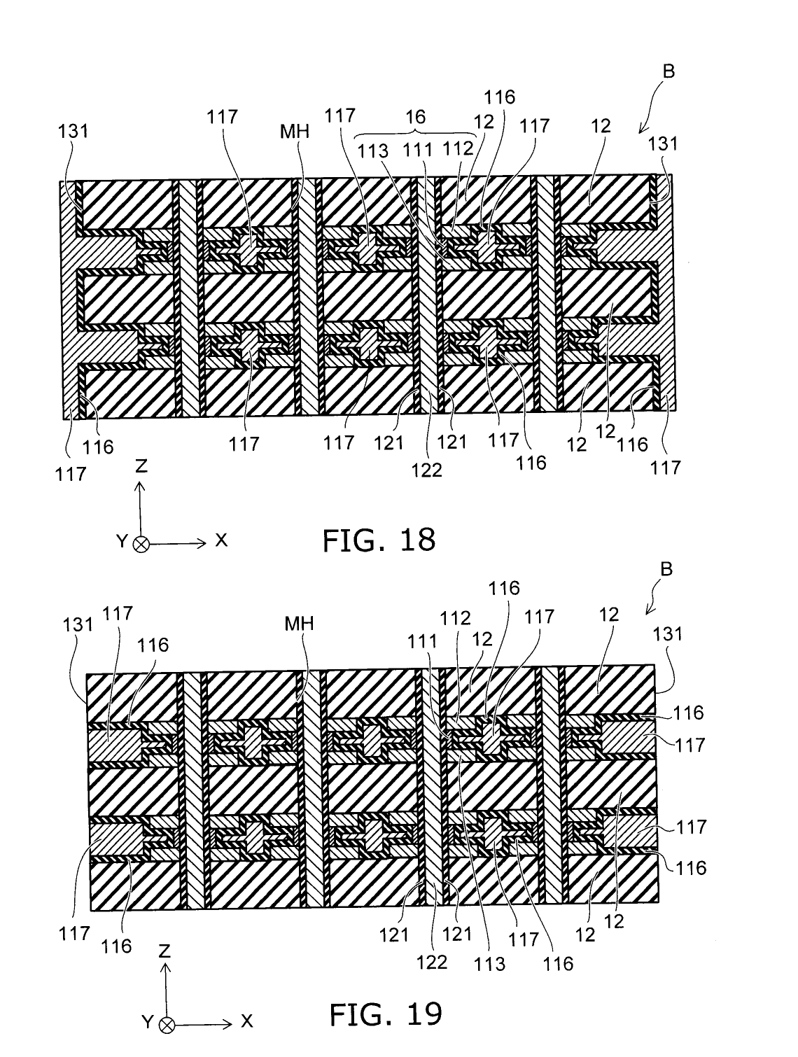

Subsequently, as shown in FIG. 18, a conductive material such as titanium nitride (TiN) and tungsten (W) is accumulated in the linear structure body 16 through the rear surface slits 131 and in the rear surface slits 131 by the LP-CVD method, for example, thereby forming the control gate electrode 117.

Subsequently, as shown in FIG. 19, RIE is performed to remove the control gate electrode 117 and the inter-electrode insulating film 116 which are formed in the rear surface slits 131. Subsequently, as shown in FIG. 20, an insulating material is embedded in the rear surface slits 131, thereby forming an insulating member 39. Thereafter, the interlayer insulating film 38 is formed on the interlayer insulating films 37, the selector gate electrodes SG2 and the insulating member 39, and then, lithography and etching is performed to form contact holes 41. Thereafter, tungsten (W), for example, is accumulated in the contact holes 41, thereby forming the contact plugs CP.

Subsequently, as shown in FIG. 1, the bit lines BL separated in the Y-direction and extend in the X-direction are provided on the contact plugs CP.

Subsequently, effects of the embodiment will be described.

In the semiconductor memory device 1 according to the embodiment, as shown in FIG. 12, after the floating gate electrode FG is formed from the memory hole MH side, as shown in FIG. 17, the inter-electrode insulating film 116 is formed from the rear surface slits 131 side. Accordingly, the floating gate electrode FG is provided in a space between the tunnel insulating film 121 and the inter-electrode insulating film 116. Therefore, the channel width D can be wide so as to be equivalent to the thickness of the linear structure body 16 without causing the tunnel insulating film 121 and the inter-electrode insulating film 116 to be in contact with each other.

As a result, cut-off characteristics of the semiconductor memory device 1 can be favorably maintained. In addition, since there is no need to increase the thickness of the linear structure body 16 in order to widen the channel width D, a small load is applied on processing.

In addition, work function of the floating gate electrode 112 may be greater than work function of the floating gate electrode 111. In that case, concentration of an electric field in a portion C shown in FIG. 2 is relaxed decreasing a flowing current, and electrical stress to the tunnel insulating film 121 is reduced, thereby improving reliability. For example, silicon in which phosphorus is doped can be used for the floating gate electrode 111, and silicon in which boron having a work function greater than that of phosphorus is doped can be used for the floating gate electrode 112.

Moreover, a material different from the materials of the floating gate electrodes 112 and 113 may be used for the floating gate electrode 111. In that case, an electrostatic capacity of the control gate electrode 117 and the floating gate electrode FG through the inter-electrode insulating film 116 can be ensured and a coupling ratio therebetween can be ensured by changing a thickness of the film of the floating gate electrode FG.

### Comparison Example of First Embodiment

Subsequently, a comparison example of the first embodiment will be described.

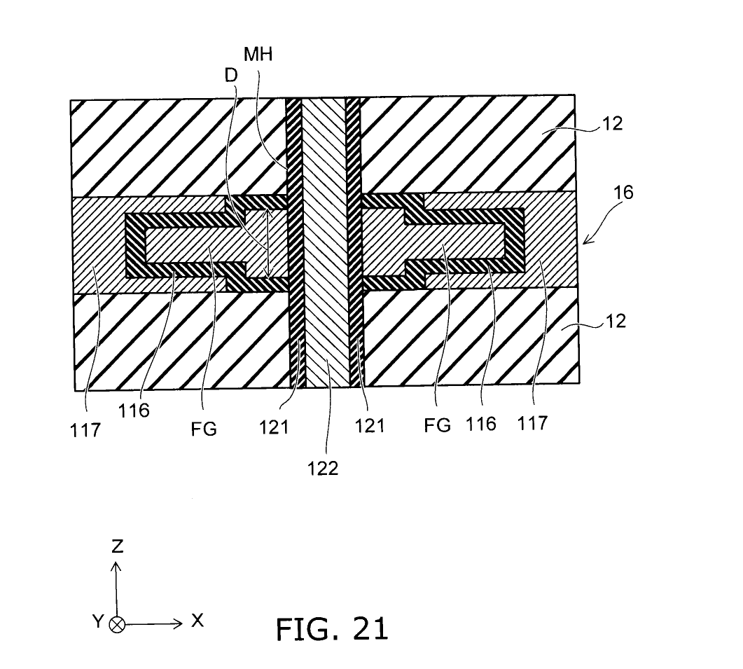

FIG. 21 is a cross-sectional view illustrating the semiconductor memory device according to the comparison example of the embodiment.

As shown in FIG. 21, in a semiconductor memory device according to the comparison example compared to the semiconductor memory device according to the embodiment (refer to FIG. 2), the inter-electrode insulating film 116 is in contact with the tunnel insulating film 121. Accordingly, a channel width D of the semiconductor memory device according to the comparison example corresponds to a thickness subtracted twice as much as the thickness of the inter-electrode insulating film 116 from the thickness of the linear structure body 16.

### Variation of First Embodiment

Subsequently, a variation of the first embodiment will be described.

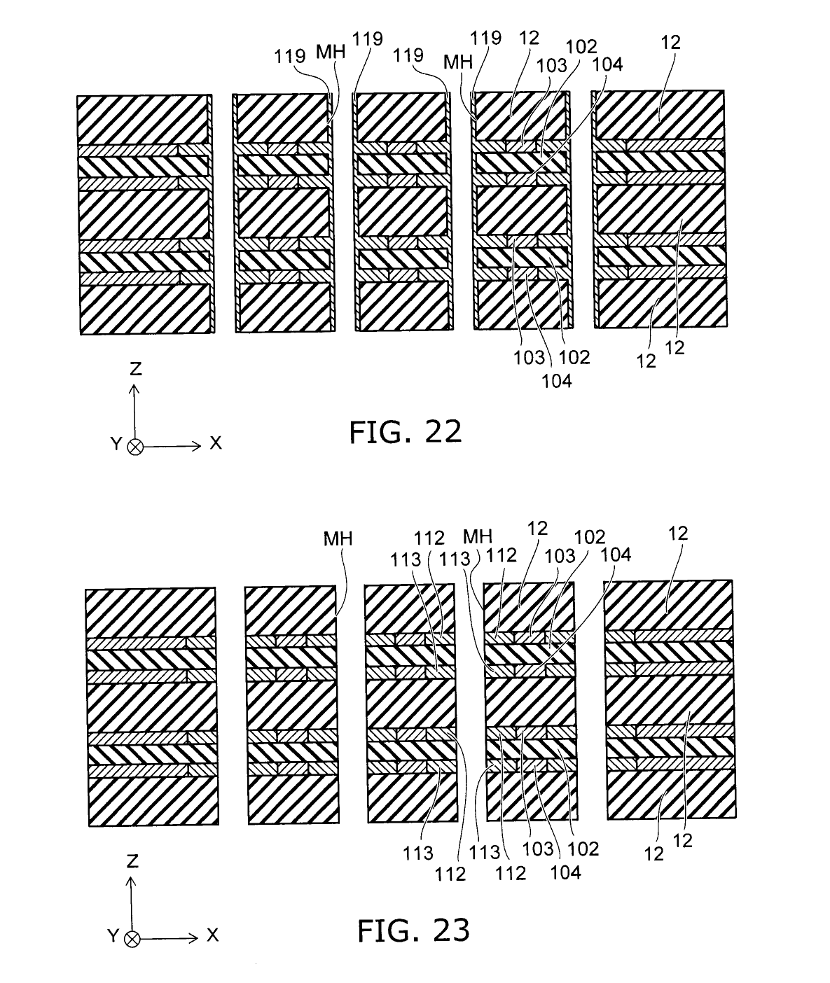

FIGS. 22 to 24 are cross-sectional views illustrating a method for manufacturing a semiconductor memory device according to the variation.

The method for manufacturing a semiconductor memory device according to the variation has a distinctive difference compared to the first embodiment in that the floating gate electrode 111 is formed after the floating gate electrode 112 and the floating gate electrode 113 are formed.

In the method for manufacturing a semiconductor memory device according to the variation, the process is similar to that of the first embodiment until the memory hole MH is formed. In other words, the process shown in FIGS. 3 to 6 is performed.

Subsequently, as shown in FIG. 22, for example, etch-back is performed on the conductive films 103 and 104 through the memory hole MH by CDE in which a hot choline aqueous solution is used as an etching solution, thereby removing a portion of each of the conductive films 103 and 104 on the memory hole MH side. As a result, the concave portion 107 is formed in a portion of the conductive film 103 on the memory hole MH side, and the concave portion 108 is formed in a portion of the conductive film 104 on the memory hole MH side. Thereafter, silicon in which phosphorus or boron is doped is accumulated on a side surface of the memory hole MH, and in the concave portion 107 and the concave portion 108 by the LP-CVD method, for example, thereby forming a conductive member 119.

Subsequently, as shown in FIG. 23, RIE is performed to remove the conductive member 119 in the memory hole MH but the conductive member 119 remains in the concave portion 107 and the concave portion 108, thereby forming the floating gate electrode 112 in a portion inside the conductive film 103 on the memory hole MH side. In addition, the floating gate electrode 113 is formed in a portion inside the conductive film 104 on the memory hole MH side. The floating gate electrode 112 and the floating gate electrode 113 are annularly formed so as to surround the memory hole MH.

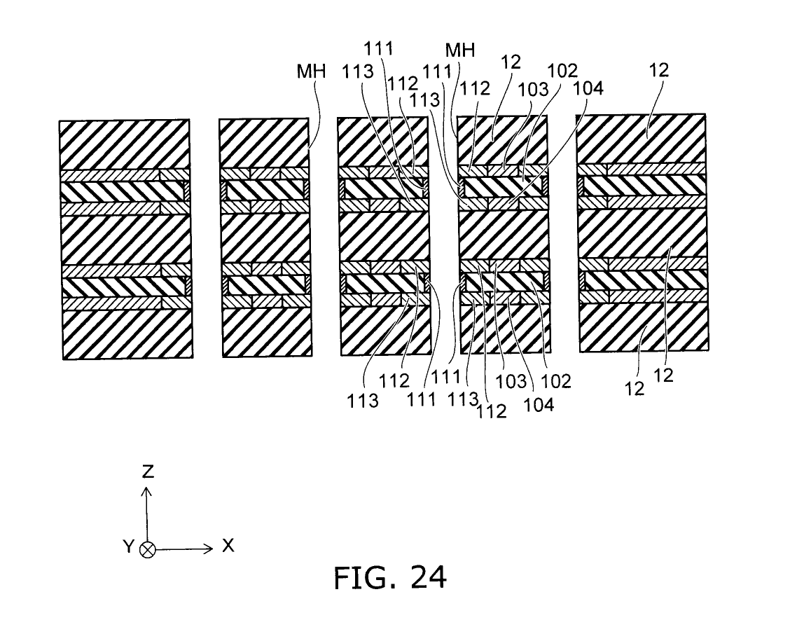

Subsequently, as shown in FIG. 24, for example, etch-back is performed on the insulating film 102 through the memory hole MH by CDE in which hot phosphoric acid is used as an etching solution, thereby removing a portion of the insulating film 102 on the memory hole MH side. As a result, the concave portion 106 is formed on a side surface of the memory hole MH.

Thereafter, silicon in which phosphorus or boron is doped is accumulated in the memory hole MH by the LP-CVD method, for example, thereby forming the conductive member 110. The conductive member 110 also enters the inside of the concave portion 106 through the memory hole MH.

Thereafter, RIE is performed to remove the conductive member 110 in the memory hole MH but the conductive member 110 remains in the concave portion 106, thereby forming the floating gate electrode 111 in a portion inside the insulating film 102 on the memory hole MH side. The floating gate electrode 111 is annularly formed so as to surround the memory hole MH.

Subsequently, the process shown in FIGS. 13 to 20 is performed.

The configuration, the manufacturing method and the effect of the variation other than those described above are similar to those of the first embodiment.

### Second Embodiment

Subsequently, a semiconductor memory device according to a second embodiment will be described.

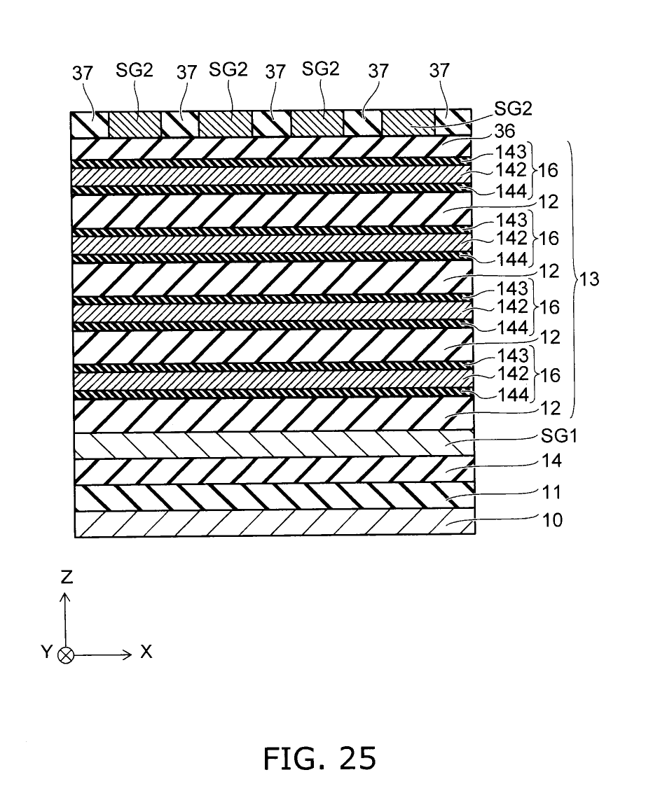

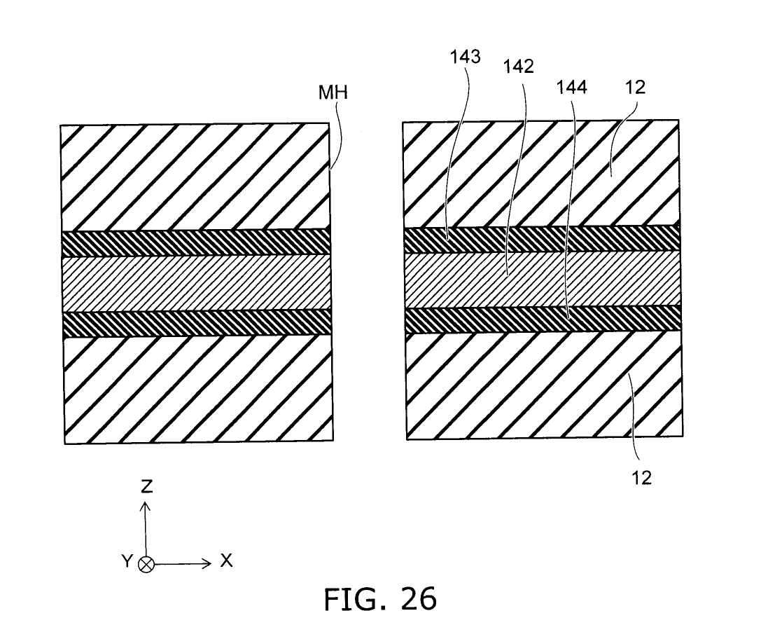

FIGS. 25 to 30 are cross-sectional views illustrating the method for manufacturing a semiconductor memory device according to the embodiment. However, FIGS. 26 to 30 illustrate a method for manufacturing a portion A shown in FIG. 1.

The method for manufacturing a semiconductor memory device according to the embodiment has distinctive differences of (a) to (c) compared to the first embodiment.

(a) A conductive film 142 made of silicon, for example, is utilized in place of the insulating film 102 in the linear structure body 16 before being processed.

(b) An insulating film 143 made of silicon oxide, for example, is utilized in place of the conductive film 103 in the linear structure body 16 before being processed.

(c) An insulating film 144 made of silicon oxide, for example, is utilized in place of the conductive film 104 in the linear structure body 16 before being processed.

In the method for manufacturing a semiconductor memory device according to the embodiment, the process is similar to the method for manufacturing the semiconductor memory device 1 according to the first embodiment until the selector gate electrode SG1 is formed. In other words, the process shown in FIG. 3 is performed.

Subsequently, as shown in FIG. 25, the interlayer insulating films 12 and the linear structure bodies 16 are alternately stacked on the selector gate electrode SG1, thereby forming the stacked body 13. The linear structure body 16 is formed by stacking the insulating film 144 made of silicon oxide, for example; the conductive film 142 made of silicon, for example; and the insulating film 143 made of silicon oxide, for example, on the interlayer insulating film 12 in order. Thereafter, the interlayer insulating film 36 is formed on the stacked body 13. Thereafter, the selector gate electrodes SG2 extending in the Y-direction and separated in the X-direction are formed on the interlayer insulating film 36. Thereafter, the interlayer insulating films 37 are embedded in gaps between the selector gate electrodes SG2.

Subsequently, as shown in FIG. 26, RIE is performed to form the memory hole MH penetrating the stacked body within the range from the selector gate electrodes SG2 to the well layer 11 in the Z-direction.

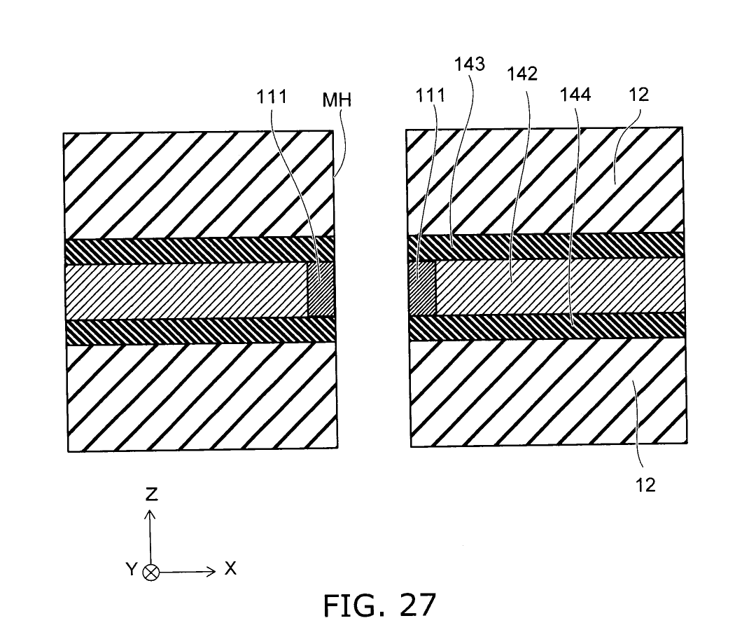

Subsequently, as shown in FIG. 27, for example, etch-back is performed on the conductive film 142 through the memory hole MH by CDE in which a hot choline aqueous solution is used as an etching solution, thereby removing a portion of the conductive film 142 on the memory hole MH side. As a result, the concave portion 106 is formed on a side surface of the memory hole MH.

Thereafter, silicon in which phosphorus or boron is doped is accumulated on a side surface of the memory hole MH and in the concave portion 106 by the LP-CVD method, for example, thereby forming the conductive member 110.

Thereafter, RIE is performed to remove the conductive member 110 in the memory hole MH but the conductive member 110 remains in the concave portion 106, thereby forming the floating gate electrode 111 in the conductive film 142. The floating gate electrode 111 is annularly formed so as to surround the memory hole MH.

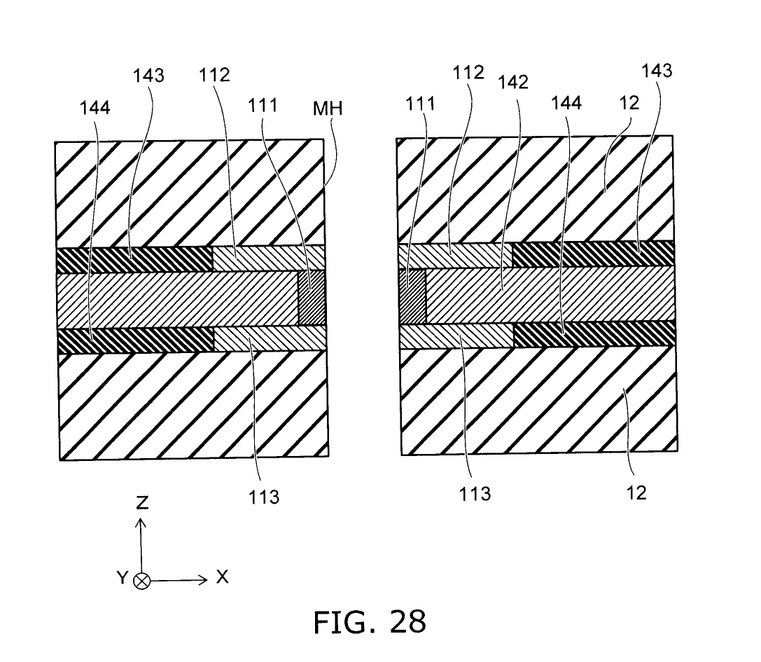

Subsequently, as shown in FIG. 28, for example, etch-back is performed on the insulating film 143 and the insulating film 144 through the memory hole MH by CDE in which hot phosphoric acid is used as an etching solution, thereby removing a portion thereof on the memory hole MH side. As a result, the concave portion 107 is formed in a portion of the insulating film 143 on the memory hole MH side, and the concave portion 108 is formed in a portion of the insulating film 144 on the memory hole MH side. In this case, since the floating gate electrode 111 is resistant to hot phosphoric acid, the floating gate electrode 111 is not removed by hot phosphoric acid.

Thereafter, silicon in which phosphorus or boron is doped is accumulated on a side surface of the memory hole MH, and in the concave portion 107 and the concave portion 108 by the LP-CVD method, for example, thereby forming a conductive member 119.

Thereafter, RIE is performed to remove the conductive member 119 in the memory hole MH but the conductive member 119 remains in the concave portion 107 and the concave portion 108, thereby forming the floating gate electrode 112 in a portion inside the insulating film 143 on the memory hole MH side. In addition, the floating gate electrode 113 is formed in a portion inside the insulating film 144 on the memory hole MH side. The floating gate electrode 112 and the floating gate electrode 113 are annularly formed so as to surround the memory hole MH.

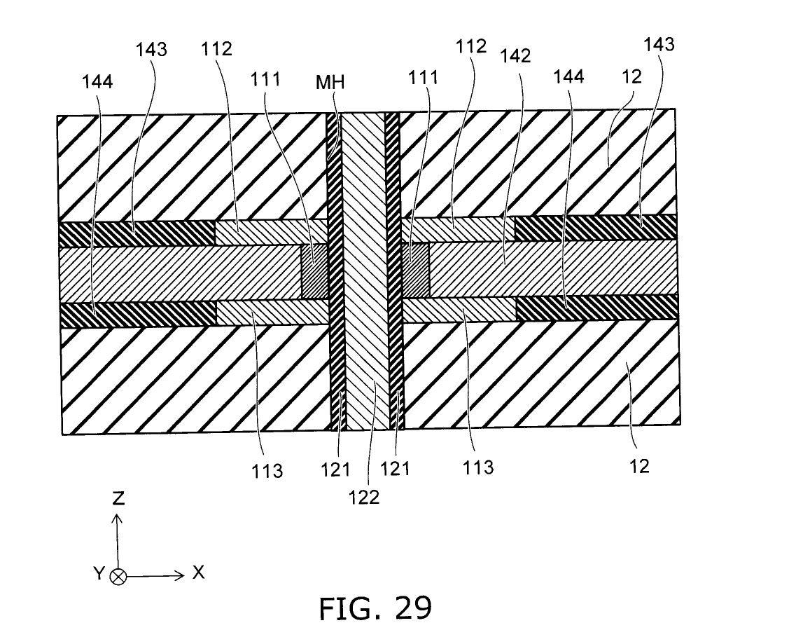

Subsequently, as shown in FIG. 29, the tunnel insulating film 121 and the silicon pillar 122 are formed similar to those of the first embodiment.

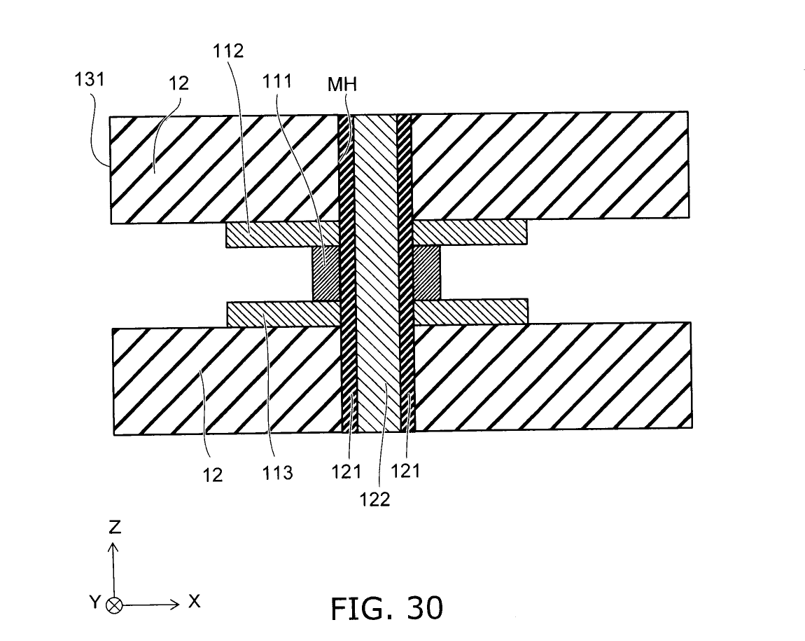

Subsequently, as shown in FIG. 30, RIE is performed to form rear surface slits 131 penetrating the stacked body within a range from the selector gate electrodes SG2 to the insulating film 14 in the Z-direction. The rear surface slits 131 are respectively formed in the four silicon pillars 122 in the X-direction, for example. The rear surface slits 131 extend in the Y-direction.

Thereafter, for example, the insulating film 143 and the insulating film 144 are removed through the rear surface slits 131 by using hot phosphoric acid as an etching solution. Thereafter, the conductive film 142 is similarly removed through the rear surface slits 131 by using a hot choline aqueous solution as an etching solution.

Subsequently, the process shown in FIGS. 17 to 20 is performed.

The configuration, the manufacturing method and the effect of the embodiment other than those described above are similar to those of the first embodiment.

### Variation of Second Embodiment

Subsequently, a variation of the second embodiment will be described.

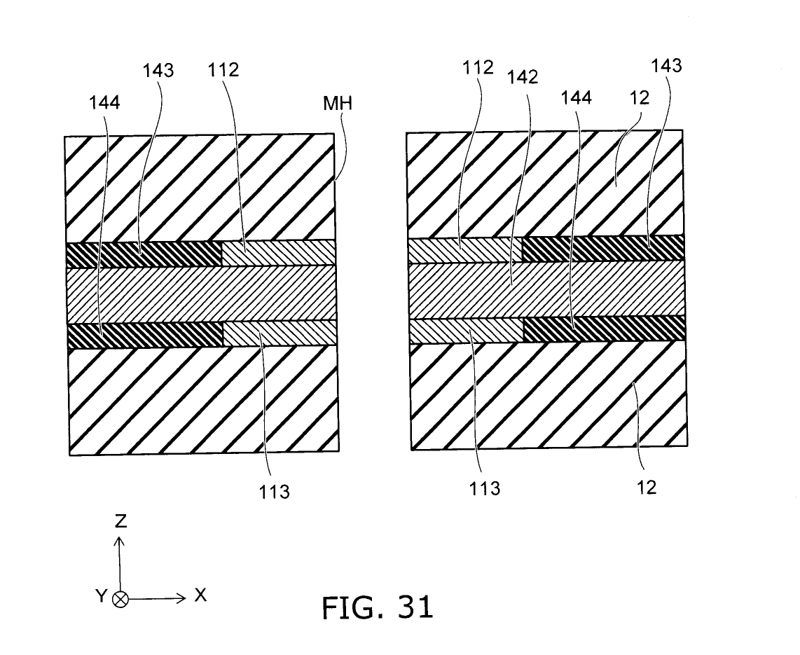

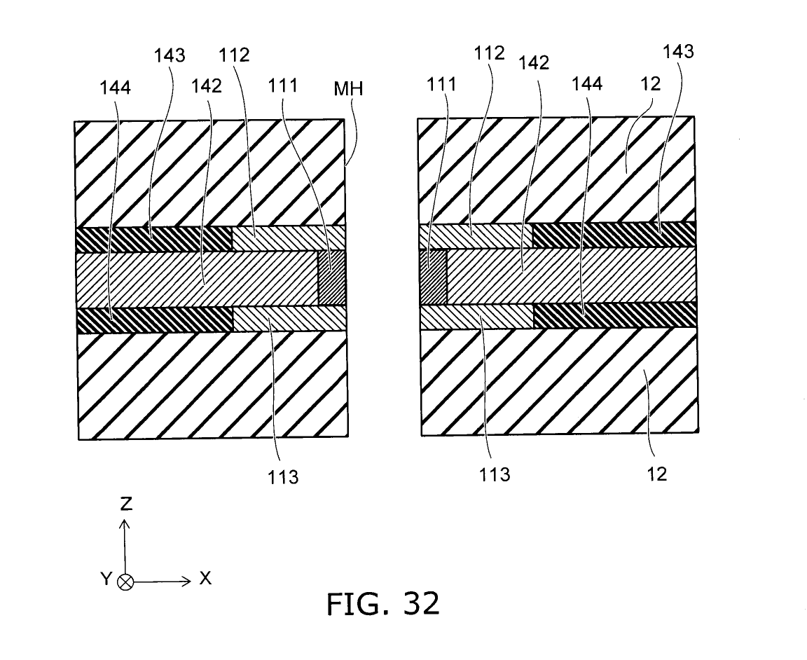

FIGS. 31 and 32 are cross-sectional views illustrating the method for manufacturing a semiconductor memory device according to the variation.

The method for manufacturing a semiconductor memory device according to the variation has a distinctive difference compared to the second embodiment in that the floating gate electrode 111 is formed after the floating gate electrode 112 and the floating gate electrode 113 are formed.

In the method for manufacturing a semiconductor memory device according to the variation, the process is similar to that of the second embodiment until the memory hole MH is formed. In other words, the process shown in FIGS. 3, 25 and 26 is performed.

Subsequently, as shown in FIG. 31, for example, etch-back is performed on the insulating film 143 and the insulating film 144 through the memory hole MH by CDE in which hot phosphoric acid is used as an etching solution, thereby removing a portion of each of the insulating film 143 and the insulating film 144 on the memory hole MH side. As a result, the concave portion 107 is formed in a portion of the insulating film 143 on the memory hole MH side, and the concave portion 108 is formed in a portion of the insulating film 144 on the memory hole MH side.

Thereafter, silicon in which phosphorus or boron is doped is accumulated on a side surface of the memory hole MH, and in the concave portion 107 and the concave portion 108 by the LP-CVD method, for example, thereby forming a conductive member 119.

Thereafter, RIE is performed to remove the conductive member 119 in the memory hole MH but the conductive member 119 remains in the concave portion 107 and the concave portion 108, thereby forming the floating gate electrode 112 in a portion inside the insulating film 143 on the memory hole MH side. In addition, the floating gate electrode 113 is formed in a portion inside the insulating film 144 on the memory hole MH side. The floating gate electrode 112 and the floating gate electrode 113 are annularly formed so as to surround the memory hole MH.

Subsequently, as shown in FIG. 32, for example, etch-back is performed on the conductive film 142 through the memory hole MH by CDE in which a hot choline aqueous solution is used as an etching solution, thereby removing a portion of the conductive film 142 on the memory hole MH side. As a result, the concave portion 106 is formed on a side surface of the memory hole MH.

Thereafter, silicon in which phosphorus or boron is doped is accumulated on a side surface of the memory hole MH and in the concave portion 106 by the LP-CVD method, for example, thereby forming the conductive member 110.

Thereafter, RIE is performed to remove the conductive member 110 in the memory hole MH but the conductive member 110 remains in the concave portion 106, thereby forming the floating gate electrode 111 on the memory hole MH side in the conductive film 142. The floating gate electrode 111 is annularly formed so as to surround the memory hole MH.

Subsequently, the process shown in FIGS. 29 and 30 is performed.

Subsequently, the process shown in FIGS. 17 to 20 is performed.

The configuration, the manufacturing method and the effect of the variation other than those described above are similar to those of the second embodiment.

### Third Embodiment

Subsequently, a semiconductor memory device according to a third embodiment will be described.

A semiconductor memory device according to the embodiment has a distinctive difference compared to the first embodiment in that the floating gate electrode 112 and the floating gate electrode 113 are formed of metal.

The floating gate electrode 112 and the floating gate electrode 113 formed of metal are also required to be resistant to a hot choline aqueous solution and hot phosphoric acid, similar to those of the first embodiment.

In addition, in the semiconductor memory device according to the embodiment, similar to the semiconductor memory device according to the first embodiment, reliability can be improved by causing work function of the floating gate electrode 112 to be greater than work function of the floating gate electrode 111, and decreasing a current flowing in the portion C shown in FIG. 2.

As a material which is resistant to a hot choline aqueous solution and hot phosphoric acid and has greater work function than work function of the floating gate electrode 111, the following materials shown in (i) can be exemplified.

(i) titanium nitride (TiN), nitrogen-containing titanium silicide (TiSixNy), carbon containing titanium silicide (TiSixCy), tantalum nitride (TaN), nitrogen-containing tantalum silicide (TaSixNy) and carbon containing tantalum silicide (TaSixCy)

The floating gate electrode 112 can be ensured to be resistant to a hot choline aqueous solution and hot phosphoric acid by being formed of the aforementioned materials shown in (i). In addition, since a current flowing in the portion C shown in FIG. 2 decreases, thereby improving reliability of the semiconductor memory device.

However, a material for the floating gate electrode 112 is not limited to the aforementioned materials shown in (i). It is acceptable as long as the material is resistant to a hot choline aqueous solution and hot phosphoric acid and allows work function of the floating gate electrode 112 to be greater than work function of the floating gate electrode 111.

The configuration, the manufacturing method and the effect of the embodiment other than those described above are similar to those of the first embodiment.

### Variation of Third Embodiment

Subsequently, a variation of the third embodiment will be described.

The method for manufacturing a semiconductor memory device according to the variation has a distinctive difference compared to the third embodiment in that the floating gate electrode 111 is formed after the floating gate electrode 112 and the floating gate electrode 113 are formed.

The configuration, the manufacturing method and the effect of the variation other than those described above are similar to those of the third embodiment.

### Fourth Embodiment

Subsequently, a fourth embodiment will be described.

A semiconductor memory device according to the embodiment has a distinctive difference compared to the second embodiment in that the floating gate electrode 112 and the floating gate electrode 113 are formed of metal.

The floating gate electrode 112 and the floating gate electrode 113 formed of metal are also required to be resistant to a hot choline aqueous solution and hot phosphoric acid, similar to those of the second embodiment.

In addition, reliability can be improved by causing work function of the floating gate electrode 112 to be greater than work function of the floating gate electrode 111, and decreasing a current flowing in the portion C shown in FIG. 2.

As a material which is resistant to a hot choline aqueous solution and hot phosphoric acid and has greater work function than work function of the floating gate electrode 111, the materials shown in (i) of the third embodiment can be exemplified.

The floating gate electrode 112 can be ensured to be resistant to a hot choline aqueous solution and hot phosphoric acid by being formed of the materials shown in (i) of the third embodiment. In addition, since a current flowing in the portion C shown in FIG. 2 decreases, reliability of the semiconductor memory device is improved.

However, a material for the floating gate electrode 112 is not limited to the materials shown in (i) of the third embodiment. It is acceptable as long as the material allows work function of the floating gate electrode 112 to be greater than work function of the floating gate electrode 111.

The configuration, the manufacturing method and the effect of the embodiment other than those described above are similar to those of the second embodiment.

### Variation of Fourth Embodiment

Subsequently, a variation of the fourth embodiment will be described.

The method for manufacturing a semiconductor memory device according to the variation has a distinctive difference compared to the fourth embodiment in that the floating gate electrode 111 is formed after the floating gate electrode 112 and the floating gate electrode 113 are formed.

The configuration, the manufacturing method and the effect of the variation other than those described above are similar to those of the fourth embodiment.

### Fifth Embodiment

Subsequently, a semiconductor memory device according to a fifth embodiment will be described.

A semiconductor memory device according to the embodiment has a distinctive difference compared to the third embodiment in that the floating gate electrode 111 is formed of metal.

The floating gate electrode 111 formed of metal is also required to be resistant to a hot choline aqueous solution and hot phosphoric acid. As a material which is resistant to a hot choline aqueous solution and hot phosphoric acid, the materials shown in (i) of the third embodiment can be exemplified. The floating gate electrode 111 can be ensured to be resistant to a hot choline aqueous solution and hot phosphoric acid by being formed of the materials shown in (i) of the third embodiment.

In the method for manufacturing a semiconductor memory device according to the embodiment, when etch-back is performed without using a hot choline aqueous solution and hot phosphoric acid, the following materials shown in (ii) can be exemplified for the floating gate electrode 111. In addition, the following materials shown in (iii) can be exemplified as materials for the floating gate electrode 112 and the floating gate electrode 113.

(ii) tungsten, titanium, tantalum, tungsten nitride, titanium nitride and tantalum nitride

(iii) metal silicide of nickel (Ni), metal silicide of cobalt (Co), metal silicide of tungsten (W) and metal silicide of titanium (Ti)

The configuration, the manufacturing method and the effect of the embodiment other than those described above are similar to those of the third embodiment.

### Variation of Fifth Embodiment

Subsequently, a variation of the fifth embodiment will be described.

The method for manufacturing a semiconductor memory device according to the variation has a distinctive difference compared to the fifth embodiment in that the floating gate electrode 111 is formed after the floating gate electrode 112 and the floating gate electrode 113 are formed.

The configuration, the manufacturing method and the effect of the variation other than those described above are similar to those of the fifth embodiment.

### Sixth Embodiment

Subsequently, a semiconductor memory device according to a sixth embodiment will be described.

A semiconductor memory device according to the embodiment has a distinctive difference compared to the fourth embodiment in that the floating gate electrode 111 is formed of metal.

The floating gate electrode 111 formed of metal is also required to be resistant to a hot choline aqueous solution and hot phosphoric acid. As a material which is resistant to a hot choline aqueous solution and hot phosphoric acid, the materials shown in (i) of the third embodiment can be exemplified. The floating gate electrode 111 can be ensured to be resistant to a hot choline aqueous solution and hot phosphoric acid by being formed of the materials shown in (i) of the third embodiment.

The configuration, the manufacturing method and the effect of the embodiment other than those described above are similar to those of the fourth embodiment.

### Variation of Sixth Embodiment

Subsequently, a variation of the sixth embodiment will be described.

The method for manufacturing a semiconductor memory device according to the variation has a distinctive difference compared to the sixth embodiment in that the floating gate electrode 111 is formed after the floating gate electrode 112 and the floating gate electrode 113 are formed.

The configuration, the manufacturing method and the effect of the variation other than those described above are similar to those of the sixth embodiment.

According to the embodiments described above, it is possible to provide a semiconductor memory device having a wide channel width, and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a semiconductor pillar extending in a first direction;
a first insulating film provided on a side surface of the semiconductor pillar;
a second insulating film provided on a side surface of the first insulating film;
a third insulating film provided apart from the second insulating film on a side surface of a second direction opposite to the first direction of the first insulating film;
a first portion of a first electrode provided in a space between the second insulating film and the third insulating film so as to be in contact with an outer surface of the first insulating film and a surface of the second direction side of the second insulating film;
a second portion of the first electrode provided in a space between the second insulating film and the third insulating film so as to be in contact with an outer surface of the first insulating film and a surface of the first direction side of the third insulating film;
a third portion of the first electrode provided in a space between the first portion of the first electrode and the second portion of the first electrode so as to be in contact with the first insulating film, the first portion of the first electrode and the second portion of the first electrode;
a forth insulating film provided on an outer surface of the first electrode, a surface of the second direction side of the second insulating film and a surface of the first direction side of the third insulating film between the second insulating film and the third insulating film; and
a second electrode provided on an outer surface of the forth insulating film between the second insulating film and the third insulating film,
an outer diameter of the first portion of the first electrode being larger than an outer diameter of the third portion of the first electrode,
an outer diameter of the second portion of the first electrode being larger than an outer diameter of the third portion of the first electrode.

2. The device according to claim 1,
wherein the first electrode is made of silicon.

3. The device according to claim 1,
wherein the third portion of the first electrode is made of silicon in which phosphorus or boron is doped, and the first portion of the first electrode and the second portion of the first electrode are made of titanium nitride, nitrogen-containing titanium silicide, carbon-containing titanium silicide, tantalum nitride, nitrogen-containing tantalum silicide, or carbon-containing tantalum silicide.

4. The device according to claim 1,
wherein the first electrode is made of titanium nitride, nitrogen-containing titanium silicide, carbon-containing titanium silicide, tantalum nitride, nitrogen-containing tantalum silicide, or carbon-containing tantalum silicide.

5. The device according to claim 1,
wherein the first portion of the first electrode and the second portion of the first electrode are made of metal silicide of nickel, cobalt, tungsten, or titanium, and the second electrode is made of tungsten, titanium, tantalum, tungsten nitride, titanium nitride, or tantalum nitride.

6. The device according to claim 1,
wherein the forth insulating film is a single layer film of silicon oxide, a stacked film made of silicon oxide and silicon nitride, a single layer film made of a high dielectric constant insulating material, or a stacked film made of the high dielectric constant insulating material, silicon oxide, and silicon nitride.

7. The device according to claim 6,
wherein the high dielectric constant insulating material is oxide or oxynitride of one or more types of metal selected from a group composed of zirconium, hafnium, tantalum, lanthanum, and aluminum.

8. The device according to claim 1,
wherein the forth insulating film includes a forth portion and a fifth portion, the forth portion is provided to be in contact with a surface of the second direction side of the second insulating film and a surface of the first direction side of the third insulating film, the fifth portion is provided to be spaced from a surface of the second direction side of the second insulating film and a surface of the first direction side of the third insulating film.

9. The device according to claim 8,
wherein the forth portion is provided on a side outer than the fifth portion.

10. The device according to claim 1,
wherein the second electrode includes a protrusion portion oriented toward the semiconductor pillar.

11. The device according to claim 1,
wherein the second electrode includes a forth portion and a fifth portion, the fifth portion is provided on a semiconductor pillar side from the forth portion, and a thickness of the forth portion in the first direction is greater than a thickness of the fifth portion in the first direction.

12. A semiconductor memory device comprising:
a stacked body including a plurality of conductive layers and a plurality of insulating layers, each of the conductive layers and the insulating layers being alternately disposed;
a semiconductor pillar extending in a first direction inside the stacked body;
a first insulating film provided in a space between the semiconductor pillar and the conductive layer;
a first portion of a first electrode provided in a space between the first insulating film and the conductive layer so as to be in contact with a second direction side surface being opposite to the first direction of the insulating film and an outer surface of the first insulating film;
a second portion of the first electrode provided in a space between the first insulating film and the conductive layer so as to be in contact with the first direction side surface of the insulating film and the first insulating film; and
a third portion of the first electrode provided to be in contact with the first insulating film, the first portion of the first electrode and the second portion of the first electrode; and
a second insulating film provided in a space between the first electrode and the conductive layer,
an outer diameter of the first portion of the first electrode being larger than an outer diameter of the third portion of the first electrode,
an outer diameter of the second portion of the first electrode being larger than an outer diameter of the third portion of the first electrode.

13. The device according to claim 12,
wherein the second insulating film includes a forth portion and a fifth portion, the forth portion is provided to be in contact with the insulating layer, the fifth portion is provided to be spaced from the insulating layer.

14. The device according to claim 13,
wherein the forth portion is provided on a side outer than the fifth portion.

15. The device according to claim 12, further comprising:
a second electrode being provided in a space between the second insulating film and the conductive layer, and includes a protrusion portion oriented toward the semiconductor pillar.

16. The device according to claim 12,
wherein the second electrode includes a forth portion and a fifth portion, the fifth portion is provided on a semiconductor pillar side from the forth portion, and a thickness of the forth portion in the first direction is greater than a thickness of the fifth portion in the first direction.

17. A method for manufacturing a semiconductor memory device comprising:
forming of a first material layer performed by causing a first material to be accumulated;
forming of a second material layer performed by causing a second material to be accumulated on the first material layer;
forming of a third material layer performed by causing a third material to be accumulated on the second material layer;
forming of a memory hole performed by penetrating a stacked body composed of the first material layer, the second material layer, and the third material layer in a stacking direction;
removing of a portion of the second material layer on the memory hole side through the memory hole;
causing a first conductive material to be accumulated in the memory hole;
forming of a first portion of a first electrode made of the first conductive material in a space after the second material layer is removed, by performing etch-back on the first conductive material;
removing a portion of each of the first material layer and the third material layer on the memory hole side through the memory hole;
causing of a second conductive material to be accumulated in the memory hole;
forming of a second portion of the first electrode made of the second conductive material in a first direction side space after the first material layer and the third material layer are removed, forming of a third portion of the first electrode made of the second conductive material in a second direction side being opposite to the first direction side space after the first material layer and the third material layer are removed, by performing etch-back on the second material layer;
forming of a first insulating film on side surfaces of the first electrode;
forming of a slit penetrating the stacked body in the stacking direction on sides of the memory hole;
removing of the first material layer, the second material layer, and the third material layer through the slit;
forming of a second insulating film on side surfaces of the first electrode through the slit; and
forming of a second electrode on a front surface of the second insulating film through the slit.

18. The method according to claim 17,
wherein the first material and the third material are conductive materials, and the second material is an insulating material.
